(19) United States
(12) Patent Application Publication
(10) Pub. No.: US 2007/0049005 A1
(43) Pub. Date: Mar. 1, 2007

(54) Method for forming dual damascene pattern in semiconductor manufacturing process

(75) Inventor: Yung Pil Kim, Icheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/511,630

(22) Filed: Aug. 28, 2006

(30) Foreign Application Priority Data
Aug. 26, 2005 (KR) 10-2005-0078847

(51) Int. Cl. H01L 21/4763

(52) U.S. Cl. 438/622

(57) ABSTRACT

A method for forming a dual damascene structure in a semiconductor manufacturing process is provided. The method includes forming a first dielectric layer and a first conductive layer on a semiconductor substrate; forming a second dielectric layer on the first conductive layer; applying a photoresist on the second dielectric layer; exposing the photoresist to using a first mask that defines a wiring region; exposing the photoresist using a second mask that defines a via hole; developing the photoresist to form a photoresist pattern having a damascene structure that includes a via hole pattern and a wiring pattern; forming the via hole and the wiring region by anisotropically etching the second dielectric layer according to the photoresist pattern; filling the via hole and the wiring region with a second conductive layer after removing the photoresist pattern; and forming a contact and a wiring by removing the second conductive from outside the via hole and the wiring region using a CMP process.

This application claims the benefit of priority to Korean Application No. 10-2005-0078847, filed on Aug. 26, 2005, which is incorporated by reference herein in its entirety.

### BACKGROUND OF THE INVENTION

1. Field of the Invention

The present invention relates to a method for manufacturing a semiconductor device. More specifically, the present invention relates to a dual damascene process using a low dielectric constant (low-k) material.

2. Description of the Related Art

Generally, as the semiconductor industry shifts to a very large-scale integration (VLSI) level, the geometry of the device continues to be narrowed to a sub-half-micron region or less. In view of improved performance and reliability, the circuit density is gradually increased.

Copper has a high tolerance to an electro-migration (EM) since it has a higher melting point than aluminum, thus, a copper metal wiring can improve reliability of the semiconductor device. Further, the copper metal wiring can increase a signal transfer speed since it has a relatively low resistivity. For these reasons, in forming a metal wiring in a semiconductor device, copper has been used as a useful interconnection material for integrated circuits.

On the other hand, as the semiconductor device is highly integrated and the related technologies are developed, many problems are caused due to a parasitic capacitance between wirings. High parasitic capacitance causes RC delay, high wattage, and noise by interference, thus the operational speed of devices is deteriorated. Thus, a dielectric material having a low-k value of three (3) or below (e.g., a porous oxide) is widely used as a material for an interlevel dielectric (ILD) layer.

However, in a wiring process using Cu (copper) and the low-k dielectric material, a typical metal film patterning process is generally not applicable because Cu has an inferior etching characteristic. To solve these problems, recently, a dual damascene process is widely used in forming a Cu metal line.

The dual damascene process is implemented in sub-0.13 μm technologies in various forms, such as a buried via formation, a via first formation, a trench first formation, and a self aligned formation.

The improvement of the operating speed of a CMOS logic device depends primarily on the reduction in the gate delay time by reducing the length of gate. Recently, a resistance capacitance (RC) delay, which is caused by a metallization of a Back End Of Line (BEOL) followed by the highly integration of device, controls the speed of the device.

To reduce the RC delay, as stated above, a metal having a low resistance such as Cu is used as a metal line material, and the ILD layer is formed with the low-k dielectric material, and further the dual damascene process is applied.

FIGS. 1A to 1E are cross-sectional views illustrating a conventional method for forming a dual damascene pattern.

Referring to FIG. 1A, a first ILD layer 100 and a first conductive layer 102 are formed on a semiconductor substrate (not shown), according to a conventional method. After that, a second ILD layer 104 is stacked, and a first photoresist 106 for photo etching process (PEP) is deposited on the second ILD layer 104. Here, for the second ILD layer 104, desirably, FSG (fluorinated silicate glass) or P-SiH₄ (a so-called “plasma silane”) oxide can be applied.

Referring to FIG. 1B, a first photoresist pattern, i.e., a via hole photoresist pattern 106′, is formed on the resultant structure of FIG. 1A, and a via hole region 108 is formed by performing a first etching to the second ILD layer 104 using the via hole photoresist pattern 106′ as a mask.

Subsequently, referring to FIG. 1C, a second photoresist is applied on the second ILD layer 104 after removing the via hole photoresist pattern 106′, thus forming a second photoresist pattern 110 by performing a photolithography process to the second photoresist. After then, a trench wiring region 112 is formed by performing a second etching to the second ILD layer 104 using the second photoresist pattern 110 as a mask.

Referring to FIG. 1D, after removing the second photoresist pattern 110 on the second ILD layer 104, the via hole region 108 and the trench wiring region 112 are filled by depositing or electrochemically plating a second conductive layer 114 on the second ILD layer 104. Here, for the second conductive layer 114, as stated above, a copper layer can be applied along with a barrier metal.

Finally, referring to FIG. 1E, the deposited or electrochemically plated second conductive layer 114 remains inside the via hole region 108 and the trench wiring region 112, after a chemical mechanical polishing (CMP) process, thus forming a contact 116 and a metal wiring 118, respectively.

According to the above described typical dual damascene process, separate via hole forming and wiring region forming processes form one wiring. There are some drawbacks in these processes, for example, that multiple photolithography processes and etching processes are used. Namely, as shown in FIGS. 1A to 1E, two photo processes and two etching processes are used to form one wiring, and these processes make the whole process flow of semiconductor device relatively complicated, thus it results in a high manufacturing price.

Additionally, as shown in FIG. 1C, in the photo/etching processes for the wiring, an additional resist filling-in process may be performed to protect the via hole region, Thus, the process may become unnecessarily complicated, and the process inferiority rate may get higher.

### SUMMARY OF TH INVENTION

Consistent with embodiments of the present invention, there is provided a method for forming a dual damascene pattern (and/or dual damascene metallization) in a semiconductor manufacturing process that can make the process simple. The present invention comprises a double exposure and a single development using masks for forming a wiring and a via hole on the same photoresist layer, and etching a trench and a via hole concurrently using an etching selectivity ratio of an ILD layer to a photoresist.

Accordingly, an embodiment consistent with the present invention provides a method for forming a dual damascene pattern in a semiconductor manufacturing process, comprising the steps of: forming a first dielectric layer and a first conductive layer on a semiconductor substrate; forming a second dielectric layer on the first conductive layer; applying a photoresist on the second dielectric layer; performing a first exposure of (e.g., exposing) the photoresist to radiation using a first mask that defines a wiring region; performing a second exposure of (e.g., exposing) the photoresist using a second mask that defines a via hole; developing the photoresist to form a photoresist pattern having a damascene structure that includes a via hole region and a wiring pattern; forming the via hole and the wiring region by anisotropically etching the second dielectric layer according to the photoresist pattern; filling the via hole and the wiring region with a second conductive layer after removing the photoresist pattern; and forming a contact and a wiring by removing the second conductive layer inform outside the via hole and the wiring region using a CMP process.

### BRIEF DESCRIPTION OF THE DRAWINGS

FIGS. 1A to 1E are cross-sectional views illustrating a conventional method for forming a dual damascene pattern.

FIGS. 2A to 2G are cross-sectional views illustrating a method for forming a dual damascene pattern, according to the present invention.

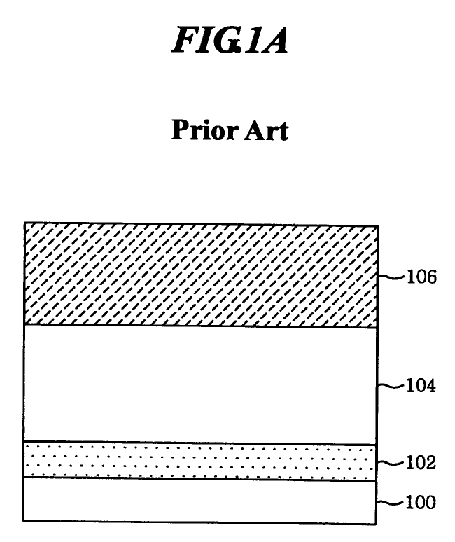

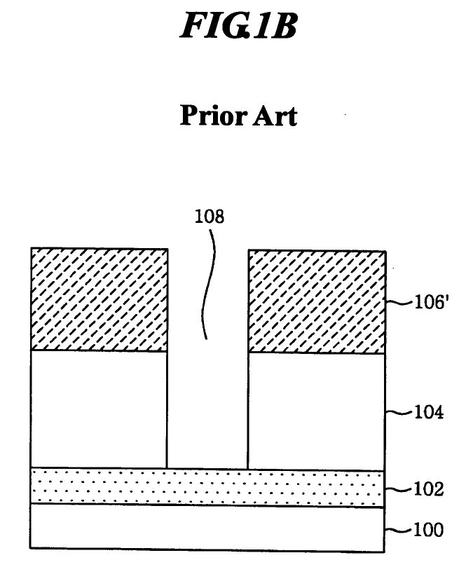

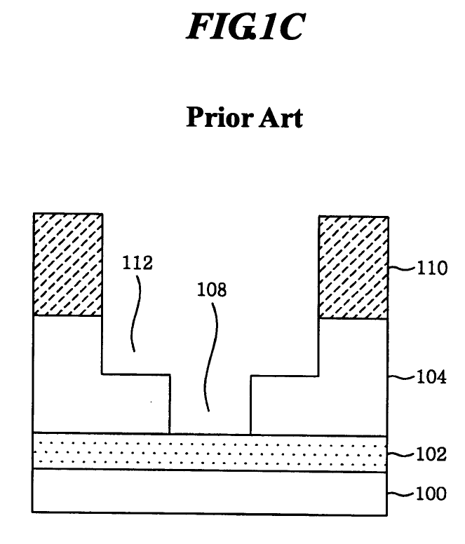

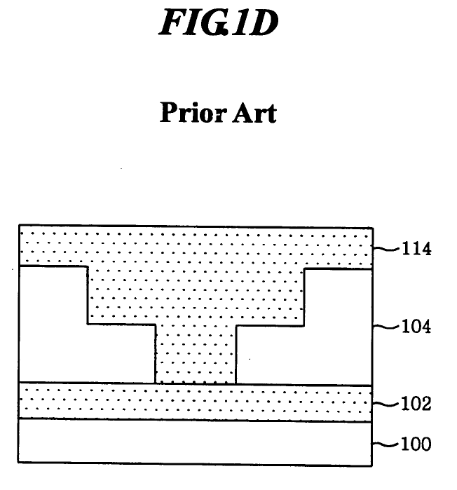

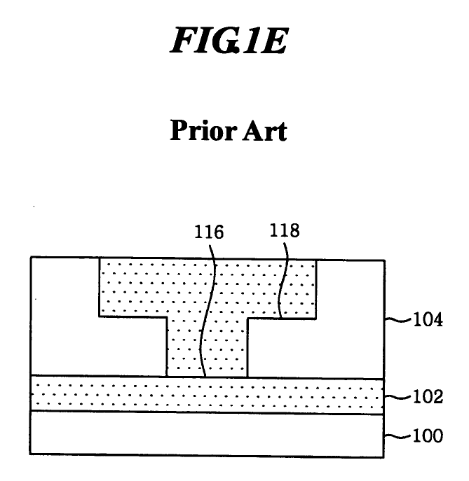

### DETAILED DESCRIPTION OF THE INVENTION

These and other aspects of the invention will become evident by reference to the following description of the invention, often referring to the accompanying drawings.

The main features of the present invention are as follows. An etching process for forming a via hole and a wiring region (i.e., a trench) utilizes the difference of an etching selectivity between an ILD layer and a photoresist. However, the present invention is different from the conventional method that forms the via hole and the wiring region in separate steps. Namely, in the present method, a portion of the photoresist over the wiring region or trench remains, while the photoresist over the via hole region is removed. In other words, the photoresist pattern has a damascene structure. While etching the via hole region, the photoresist remaining over the wiring region is etched according to its etching selectivity. Thus, by the time that the via hole etching is finished, the desired wiring region has also been etched to the desired or predetermined depth in the dielectric layer.

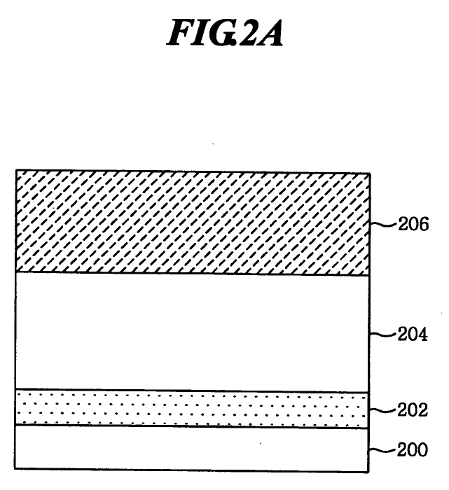

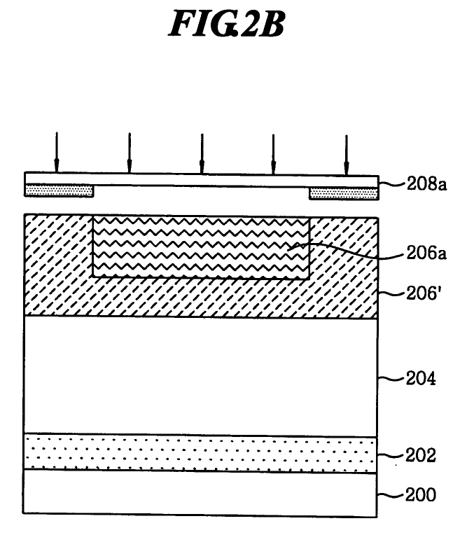

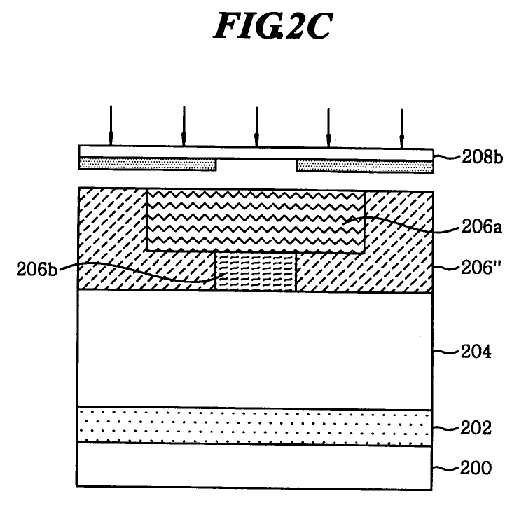

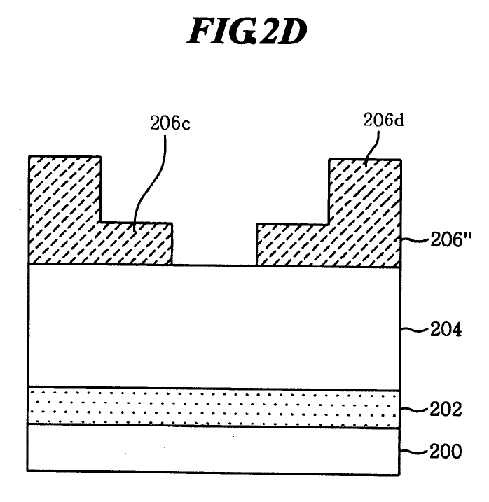

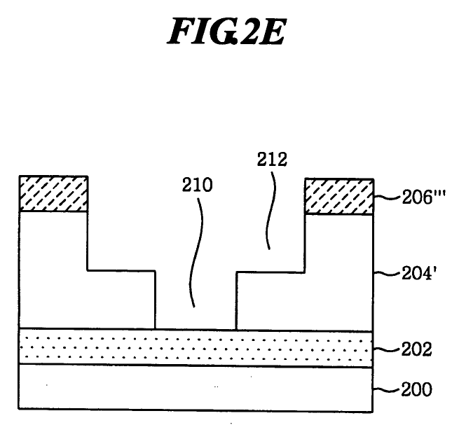

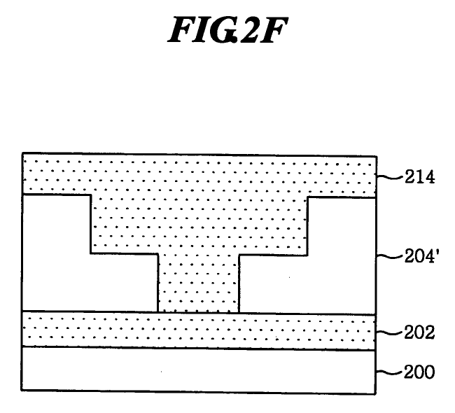

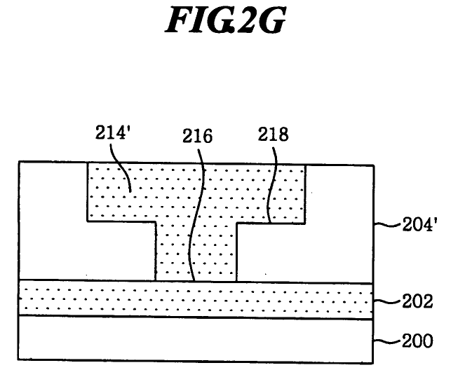

FIGS. 2A to 2G are cross-sectional views illustrating a method for forming a dual damascene pattern, according to the present invention.

Referring to FIG. 2A, a first interlayer dielectric (ILD) layer 200 and a first conductive layer 202 are formed on a semiconductor substrate by a typical method, and a second ILD layer 204 is deposited, and further a photoresist 206 is applied on the second ILD layer 204. Here, a capping or etch stop layer comprising a SiN layer can be additionally formed on the first conductive layer 202. The capping layer can function as a etch stop layer in a subsequent etching process of the second ILD layer 204. Also, for the second ILD layer 204, a composite layer, such as a fluorosilicate glass (FSG), plasma silane (P-SiH₄) oxide, “black diamond” (e.g., silicon oxycarbide [SiOC] or hydrogenated silicon oxycarbide [SiOCH]), etc., can be applied. Further, it is desirable that the thickness of the second ILD layer 204 is twice or more than that of the wiring, in order to improve the dielectric characteristic and process margin. Especially, it is desirable to use a low-k ILD layer to achieve a lower parasitic capacitance.

FIG. 2B to FIG. 2C are illustrating a process of performing a dual exposure process to form the wiring pattern and the via hole region in the photoresist, according to the present invention.

Firstly, as shown in FIG. 2B, a wiring definition region 206a is determined by performing a first exposure to the photoresist 206 using a first mask 208a that exposes the wiring region to light having a wavelength effective to change the solubility of the photoresist in a subsequently-used developer. Here, it is preferable that a bottom part 206′ of the photoresist 206 is not exposed to light. A selective exposure can be embodied by not applying the exposure process to a certain thickness of the bottom part of the photoresist 206 by adjusting the exposure amount. Thus, in one aspect, the light (or radiation) through the first mask comprises an amount or dose sufficient to change a solubility of a partial thickness, but not an entire thickness, of the photoresist in a subsequent developer. Alternatively, the mask may contain an opaque region or a phase-shifted region corresponding to the wiring definition region (or pattern) 206a, having characteristics effective to change a solubility of a partial thickness, but not an entire thickness, of the photoresist in a subsequent developer.

Then, referring to FIG. 2C, a via hole definition region 206b is determined by performing a second exposure of the photoresist 206 to such solubility-changing radiation (light) using a second mask 208b that exposes a via hole region. Thus, the light (or radiation) through the second mask may comprise an amount or dose sufficient to change the solubility of an entire thickness of the photoresist in the subsequent developer. In such a case, the second mask does not contain an opaque region or a phase-shifted region corresponding to the via hole region 206b.

Subsequently, referring to FIG. 2D, a developing process is performed to the resultant structure of FIG. 2C. Namely, patterning the wiring definition region 206a and the via hole definition region 206b concurrently by developing the exposed photoresist of FIG. 2B and FIG. 2C forms a photoresist pattern having a dual damascene structure 206″ according to the present invention. In the photoresist pattern of (dual) damascene structure 206″, for the wiring definition region 206a, the bottom part of the photoresist pattern remains within the wiring definition region because of the difference of exposure amounts or doses, or the differences of the first and second masks in the exposed regions. Thus, finally formed photoresist pattern 206″ includes a via hole pattern part 206c that defines the via hole region and a wiring pattern part 206d that defines the wiring region, and the via hole pattern part 206c and the wiring pattern part 206d have a terraced structure. While a negative photoresist system is shown if FIGS. 2B-2D, one skilled in the art can easily devise a positive photoresist system that provides the same structure.

Here, in the present embodiment, for a selective etching in the etching process that will be described later, it is advantageous to keep the via hole pattern part 206c (i.e., the remaining portion) in the photoresist pattern of damascene structure 206″ at a certain thickness. For example, given that the thickness of the second ILD layer 204 is “t1”, the thickness of a desired line is “t2”, and the etching selectivity ratio of the photoresist 206 and the second ILD layer 204 is “1:s”, the remaining thickness “T” at the via hole pattern part 206c of the photoresist pattern 206″ of damascene structure can be expressed as the following formula.
T=(t2−t2)/s [formula 1]

However, the remaining thickness “T” of the via hole pattern part of photoresist pattern 206″ in the formula 1 is only for defining the most ideal thickness. In practice, one may set the “T” value thicker for sufficient via hole etching margin.

On the other hand, referring to FIG. 2E, the via hole and the wiring region are etched using the photoresist pattern having a (dual) damascene structure 206″ according to the present embodiment. Namely, an etched second ILD layer 204′ is formed by performing an anisotropic etching process, according to the photoresist pattern of damascene structure 206″ (i.e., using photoresist pattern 206″ as a mask, such that portion 206d is a complete mask, and portion 206c is a partial mask for the wiring region 212).

As shown in FIG. 2E, a via hole region 210 of the etched second ILD layer 204′ is etched to a depth of (T*s). A wiring region 212 of the etched second ILD layer 204′ is masked by the photoresist pattern 206′″ during the etching process of the ILD layer 204′, after then it is etched to a depth of t2.

As shown in FIG. 2F, the photoresist pattern 206′″ is removed, and a second conductive layer 214 is deposited, thus filling the via hole region 210 and the wiring region 212. Here, for the second conductive layer 214, preferably, a Cu layer including a metal barrier can be applied. Also, before forming the second conductive layer 214, a metal barrier can be formed along an exposed surface of the second ILD layer 204′, i.e. inside wall of the via hole and the wiring region. For the metal barrier, a Ti layer “e.g., as an adhesive layer immediately adjacent to the dielectric layer 204”) or a Ti/TiN bilayer (e.g., comprising a Ti adhesive layer immediately adjacent to the dielectric layer 204′ and a TiN diffusion barrier layer thereon) can be used.

Finally, as shown in FIG. 2G, a via contact region 216 and a wiring region 218 are formed, respectively, by remaining a portion of the second conductive layer 214 inside the via hole region 210 and the wiring region 212 using a CMP process.

As described in the above, in the present invention, the dual damascene pattern can be formed through only one and half times of the photolithography process and one time of the etching process.

According to the present invention, the whole process can be simplified by reducing the number of photolithography and etching processes, thus, the manufacturing price can be extremely reduced. Further, an additional process such as applying a photoresist is not needed. Thus, the yield and reliability of semiconductor devices can be improved by reducing the product defective proportion in the process.

While the invention has been shown and described with reference to certain preferred embodiments thereof, it will be understood by those skilled in the art that various changes in form and details may be made therein without departing from the spirit and scope of the invention as defined by the appended claims.

What is claimed:

1. A method for forming a dual damascene pattern, comprising the steps of:
forming a first dielectric layer and a first conductive layer on a semiconductor substrate;
forming a second dielectric layer on the first conductive layer;
applying a photoresist on the second dielectric layer;
exposing the photoresist to radiation through a first mask that defines a wiring region;
exposing the photoresist to radiation through a second mask that defines a via hole;
developing the photoresist to form a photoresist pattern having a dual damascene structure, wherein the damascene structure includes a via hole pattern and a wiring pattern;
forming the via hole region and the wiring region by anisotropically etching the second dielectric layer according to the photoresist pattern;
filling the via hole region and the wiring region with a second conductive layer after removing the photoresist pattern; and
forming a contact and a wiring by removing the second conductive layer from outside of the via hole region and the wiring region using a CMP process.

2. The method of claim 1, wherein the second dielectric layer comprises FSG and P-SiH₄ an undoped silicon oxide.

3. The method of claim 2, wherein the thickness of the second dielectric layer is at least twice that of the wiring region.

4. The method of claim 1, wherein the radiation through the first mask comprises an amount or dose sufficient to change a solubility of a partial thickness of the photoresist in a subsequent developer.

5. The method of claim 1, wherein the damascene structure has a terraced structure between the via hole region and the wiring region.

6. The method of claim 5, wherein, in the photoresist pattern, the thickness of the via region, T, is (t1-t2)/s or thicker, wherein:
t1 is the thickness of the second dielectric layer;
t2 is a desired line thickness; and
s is an etching selectivity ratio of the second dielectric layer to the photoresist.

7. The method of claim 6, wherein, in the anisotropic etching process, the via hole region of the second dielectric layer has a depth of T*s;
the wiring region of the second dielectric layer other than the via hole region is masked by the photoresist pattern during initial etching of the second dielectric layer; and
the wiring region of the second dielectric layer is etched to a depth of t2.

8. The method of claim 1, wherein the second conductive layer includes Cu.

9. The method of claim 8, wherein the second conductive layer further includes a metal barrier.

10. The method of claim 9, wherein the metal barrier comprises a Ti layer or a Ti/TiN bilayer.

11. A dual damascene method, comprising:
exposing a photoresist on a dielectric layer to radiation through a first mask that defines a wiring region;
exposing the photoresist to radiation through a second mask that defines a via hole;
developing the photoresist to form a photoresist pattern having a dual damascene structure;
forming the via hole and the wiring region by anisotropically etching the second dielectric layer; and
forming a contact and a wiring comprising a conductive layer in the via hole and the wiring region.

12. The method of claim 11, wherein the second dielectric layer comprises a fluorosilicate glass.

13. The method of claim 11, wherein the second dielectric layer comprises an undoped silicon oxide.

14. The method of claim 13, wherein forming the undoped silicon oxide comprises plasma assisted chemical vapor deposition of the undoped silicon oxide from a silane and an oxygen source.

15. The method of claim 11, wherein the radiation through the first mask comprises an amount or dose sufficient to change a solubility of a partial thickness, but not an entire thickness, of the photoresist in a subsequent developer.

16. The method of claim 11, wherein the conductive layer includes Cu.

17. The method of claim 15, wherein the conductive layer further includes a metal barrier.

18. The method of claim 16, wherein the metal barrier comprises a TiN layer.

19. The method of claim 17, wherein the metal barrier further comprises a Ti layer.

20. The method of claim 11, wherein the dielectric layer is on a semiconductor substrate further comprising an insulating layer and an at least partially exposed metallization layer, the method further comprises removing the photoresist pattern, and forming the conductive layer comprises filling the via hole and the wiring region with the conductive layer and removing the conductive layer outside the via hole and the wiring region by a CMP process.
